(19) United States
(12) Patent Application Publication
(10) Pub. No.: US 2009/0231778 A1
(43) Pub. Date: Sep. 17, 2009

(54) HIGH FREQUENCY ELECTRICAL ELEMENT

(75) Inventors: Shigeru Hiura, Tokyo (JP); Hiroaki Yamazaki, Yokohama-shi (JP); Tamio Ikehashi, Yokohama-shi (JP)

Correspondence Address: OBLON, SPIVAK, MCCLELLAND MAIER & NEUSTADT, P.C., 1940 DUKE STREET, ALEXANDRIA, VA, 22314, US

(73) Assignee: KABUSHIKI KAISHA TOSHIBA, Tokyo (JP)

(21) Appl. No.: 12/402,031

(22) Filed: Mar. 11, 2009

(30) Foreign Application Priority Data
Mar. 12, 2008 (JP) 2008-063161

(51) Int. Cl. H01G 5/16; B81B 7/02; B81B 7/04

(52) U.S. Cl. 361/290; 310/300

(57) ABSTRACT

A high frequency MEMS 1 as a high frequency electrical element has a silicon substrate 2 wholly formed with an insulation film, a first signal line 4 provided on the silicon substrate 2, a second signal line 5 provided on the silicon substrate 2, the second signal line 5 crossing the first signal line 4 within a first region above the silicon substrate 2, and a dielectric film 9 interposed between the first signal line 4 and the second signal line 5, and provided on one of the first signal line 4 and the second signal line 5, within the first region, the first signal line 4 and the second signal line 5 being relatively movable in directions for a contacting approach and a mutual spacing in between.

### CROSS REFERENCE TO RELATED APPLICATION

This application is based upon and claims the benefit of priority from prior Japanese Patent Application 2008-63161 filed on Mar. 12, 2008, the entire contents of which are incorporated herein by reference.

### BACKGROUND OF THE INVENTION

1. Field of the Invention

The present invention relates to a high frequency electrical element, and particularly, to a high frequency electrical element adapted for implementation of a variable capacitor provided with a dielectric film, having a high Q value.

2. Description of Relevant Art

Recent years have observed emerging developments of high frequency MEMS (micro electro mechanical systems) being a miniature component fabricated as a high frequency electrical element by use of micro-fabrication techniques for semiconductors. Those high frequency MEMS are advantageous in that they have a reduced transmission loss even for high frequencies of transmission signals such as in a microwave band or millimeter waveband, and are adapted for high power transmission signals to have a small distortion of waveform at high frequencies. Accordingly, for the high frequency MEMS, there are expected applications such as to switches and variable capacitors for high frequency use.

The high frequency MEMS, being fabricated by use of semiconductor fabrication techniques, can be integrated on the same silicon substrate as conventional circuits using a silicon semiconductor, such as high frequency amplifier or power supply, permitting the components to be miniaturized in size or reduced in cost.

However, for a high frequency circuit formed on a silicon substrate, the high frequency characteristics may be degraded by an effect of the silicon substrate. To this point, Japanese Patent Publication No. 3,818,176 has proposed employing a high-resistance silicon substrate, and Japanese Patent Application Laid-Open Publication No. 2005-277,675 has disclosed a structure provided with an air gap between a downside of a high frequency MEMS portion and a silicon substrate.

FIG. 10A is a plan of a general high frequency MEMS including a variable capacitor, FIG. 10B, a section along line XB-XB of FIG. 10A, and FIG. 10C, a section along line XC-XC of FIG. 10A. FIG. 10B illustrates a state of the high frequency MEMS with a lower electrode voltage turned off, and FIG. 10C illustrates a state of the high frequency MEMS with a lower electrode voltage turned on.

As illustrated in FIG. 10B, the high frequency MEMS has a silicon substrate 100 insulated by an insulation film 101. On the insulated silicon substrate 100, as illustrated in FIG. 10A, it has arranged a ground line 102, an RF signal line 103 as a high frequency signal line, an upper electrode 104, and a lower electrode 105. The RF signal line 103 is given an RF signal S. The upper electrode is formed as a conductive beam 106 bridging corresponding parts of the ground line 102. The RF signal line 103 crosses the beam 106 in a local region above the silicon substrate 100, where a dielectric film 108 is interposed as an insulator in between. The dielectric film 108 is attached to the RF signal line 103. The high frequency MEMS is thus configured to have, between the RF signal line 103 and corresponding parts of the ground line 102, a variable capacitor 107 composed of the upper electrode 104 to be actuated by the lower electrode 105 in an electrostatic manner, the dielectric film 108, and surrounding air.

The lower electrode 105 is adapted to have a voltage turned off as illustrated in FIG. 10B, and turned on as illustrated in FIG. 10C, whereby the beam 106 is moved up and down as illustrated by arrows 109, changing capacitance of the variable capacitor 107 between ground line 102 and RF signal line 103. The variable capacitor 107 has a small capacitance with the lower electrode 105 in a voltage-off state as in FIG. 10B, and has an increased capacitance about several pF with the lower electrode 105 in a voltage-on state as in FIG. 10C.

### SUMMARY OF THE INVENTION

It however is difficult for techniques disclosed in Japanese Patent Publication No. 3,818,176 and Japanese Patent Application Laid-Open Publication No. 2005-277,675 to implement a variable capacitor with a high Q value for a circuit loss reduction.

For instance, the configuration of variable capacitor illustrated as a general high frequency MEMS in FIG. 10A has such an issue that follows: FIG. 11 illustrates an equivalent circuit of, as superposed on a section of, a high frequency circuit with a ground line 102 and an RF signal line 103 formed on a silicon substrate 100 insulated by an insulation film 101, and a developed equivalent circuit of the same. As illustrated in FIG. 11, the RF signal line 103 and associated parts of the ground line 102 have capacitances C and resistances through corresponding portions of the silicon substrate 100 in between, which cause circuit losses degrading the Q value.

Most variable capacitors as high frequency MEMS are connected between such a combination of RF signal line and ground line on an insulated silicon substrate. FIG. 12 illustrates an equivalent circuit of, as superposed on a section of, a high frequency circuit having a variable capacitor added to the high frequency circuit of FIG. 11, and a developed equivalent circuit of the same. The variable capacitor is made up by a lower electrode 105 on the substrate 100, an upper electrode as a beam 106 bridging associated parts of the ground line 102, a dielectric film 108 on the RF signal line 103, and surrounding air. The beam 106 has inductances and resistances depending on lengths of two arms thereof. The variable capacitor has a characteristic Q value defined by the real part “Re (Zin)” and the imaginary part “Im (Zin)” of an impedance Zin thereof, such that:

Q=|Im(Zin)|/|Re(Zin)|

As illustrated in FIG. 12, the RF signal line 103 and associated parts of the ground line 102 have capacitances C and resistances through corresponding portions of the silicon substrate 100 in between, whereby the variable capacitor as high frequency MEMS has a degraded Q value.

The present invention has been devised in view of such points. It therefore is an object of the present invention to provide a high frequency electrical element including a variable capacitor implemented with a high Q value, allowing for a reduced circuit loss.

To achieve the object described, according to a first aspect of the present invention, a silicon substrate wholly formed with an insulation film, a first signal line provided on the silicon substrate, a second signal line provided on the silicon substrate, the second signal line crossing the first signal line within a first region above the silicon substrate, and a dielectric film interposed between the first signal line and the second signal line, and provided on one of the first signal line and the second signal line, within the first region, the first signal line and the second signal line being relatively movable in directions for a contacting approach and a mutual spacing in between.

According to a second aspect of the present invention, in the high frequency electrical element according to the first aspect, a first portion as part of the first region, a second portion extending in a second region different from the first region, the second portion being connected to the first portion, and spaced from the silicon substrate more than the first portion, and a third portion connected to the second portion and a coplanar line formed to the silicon substrate for external connection.

According to a third aspect of the present invention, in the high frequency electrical element according to the first aspect, an electrode for electrostatic force for the second signal line to be movable above the silicon substrate is disposed at a lateral side of the second signal line, and the electrode for electrostatic force and the second signal line are linked to each other by a linking insulator.

According to a fourth aspect of the present invention, the high frequency electrical element according to the third aspect comprises a capacitor bank composed of a plurality of series-connected unit structures each respectively comprising an electrode for electrostatic force disposed at a lateral side of the second signal line, the electrode for electrostatic force being linked to the second signal line by a linking insulator, and the second signal line being connected to a metal electrode on the silicon substrate.

According to a fifth aspect of the present invention, the high frequency electrical element according to the third aspect comprises a capacitor bank composed of a plurality of series-connected unit structures each respectively comprising an electrode for electrostatic force disposed at a lateral side of the second signal line, the electrode for electrostatic force being linked to the second signal line by a linking insulator, and the second signal line floating relative to the silicon substrate.

### BRIEF DESCRIPTION OF THE DRAWINGS

FIG. 1A is a plan of a high frequency electrical element according to a first embodiment of the present invention.

FIG. 1B is a section along line IB-IB of FIG. 1A.

FIG. 1C is a section along line IC-IC of FIG. 1A.

FIG. 2 is a graph of Q characteristic curves of the high frequency electrical element of FIG. 1A.

FIG. 3 is an equivalent circuit diagram of the high frequency electrical element of FIG. 1A.

FIG. 4A is a plan of a high frequency electrical element according to a second embodiment of the present invention.

FIG. 4B is a section along line IVB-IVB of FIG. 4A.

FIG. 5 is a graph of Q characteristic curves of the high frequency electrical element of FIG. 4A.

FIG. 6 is a plan of a high frequency electrical element according to a third embodiment of the present invention.

FIG. 7A is a plan of a high frequency electrical element according to a fourth embodiment of the present invention.

FIG. 7B is a detail of part VIIB of FIG. 7A.

FIG. 7C is a section along line VIIC-VIIC of FIG. 7B.

FIG. 8A is a plan of a high frequency electrical element according to a fifth embodiment of the present invention.

FIG. 8B is a detail of part VIIIB of FIG. 8A.

FIG. 8C is a section along line VIIIC-VIIIC of FIG. 8B.

FIG. 9A is a circuit diagram including a high frequency electrical element according to an embodiment of the present invention.

FIG. 9B is another circuit diagram including a high frequency electrical element according to an embodiment of the present invention.

FIG. 9C is another circuit diagram including a high frequency electrical element according to an embodiment of the present invention.

FIG. 10A is a plan of a general high frequency MEMS including a variable capacitor.

FIG. 10B is a section along line XB-XB of FIG. 10A.

FIG. 10C is a section along line XC-XC of FIG. 10A.

FIG. 11 is an equivalent circuit diagram of a fundamental portion of the high frequency MEMS of FIG. 10A.

FIG. 12 is an equivalent circuit diagram of an essential portion including the variable capacitor of the high frequency MEMS of FIG. 10A.

### DETAILED DESCRIPTION OF THE PREFERRED EMBODIMENTS

There will be described the preferred embodiments of the present invention with reference to the drawings.

### First Embodiment

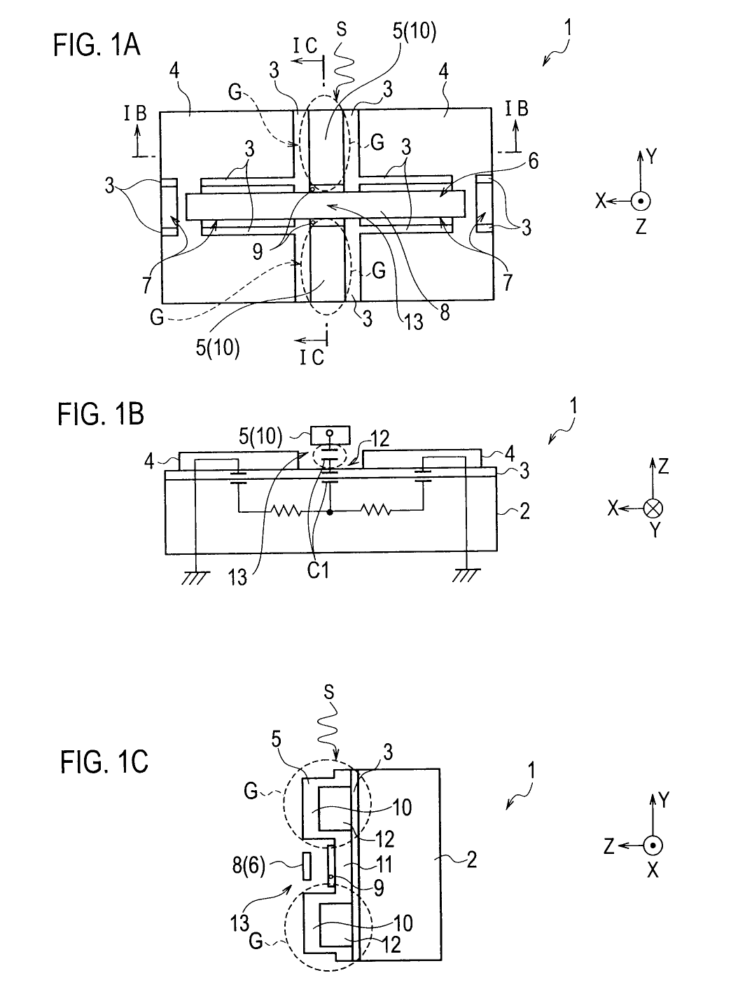

FIG. 1A is a plan of a high frequency MEMS 1 as a high frequency electrical element according to a first embodiment of the present invention, FIG. 1B, a section along line IB-IB of FIG. 1A, and FIG. 1C, a section along line IC-IC of FIG. 1A.

As illustrated in FIG. 1A and FIG. 1B, the high frequency MEMS 1 has a silicon substrate 2 insulated by an insulation film 3. On this insulated silicon substrate 2, a first signal line 4 and a second signal line 5. The first signal line 4 is a ground line (referred herein sometimes to “ground”) 4, the second signal line 5 is an RF signal line 5 as a high frequency signal line. Further thereon, it has arranged an upper electrode 6 composed of a conductive beam 8 (as a ground portion ‘associated’ in a manner of) bridging corresponding ground portions of the ground line 4 for instance, a lower electrode 7 disposed on the silicon substrate 2 in a vertically opposing manner relative to the upper electrode 6, and a dielectric film 9 as an insulation film interposed between the RF signal line 5 and the upper electrode 6.

The RF signal line 5 has a portion connected to an external high frequency electric circuit as another high frequency electrical element, by a coplanar line formed to the insulated silicon substrate 2. The RF signal line 5 has, in a local region above the insulated silicon substrate 2, a corresponding portion thereof crossing the upper electrode 6.

The upper electrode 6 and the lower electrode 7 have a control voltage applied across them for an electrostatic action to be described later. The upper electrode 6 is connected to the above-noted corresponding ground portions of the ground line 4, and has a ground potential, and the lower electrode 7 has an electrostatic potential corresponding to the control voltage. The lower electrode 7 is configured as an electrode for producing electrostatic forces to actuate the beam 8 of the upper electrode 8 to move in a Z-axis direction. The upper electrode 6 and the lower electrode 7 extend in an X-axis direction, and the RF signal line 5 extends in a Y-axis direction.

In the embodiment illustrated in FIG. 1A, the dielectric film 9 is formed as part of a variable capacitor 13 on an intermediate part of the RF signal line 5. It is noted that a dielectric film or dielectric films 9 may well be formed on one or both of mutually opposing surfaces of the beam 8 and the corresponding portion of RF signal line 5 crossing each other in the above-noted local region.

As illustrated in FIGS. 1A and 1C, in each of local regions (within enclosing broken lines G) different from the above-noted local region above the silicon substrate 2, a corresponding portion of the RF signal line 5 is spaced, i.e., floated, off from the silicon substrate 2, more than in other regions, thereby defining an air layer 12. The portion within enclosing broken line G is formed as a rectangular convex portion 10 that is convex in the Z-axis direction.

Rectangular convex portions 10 of the RF signal line 5 are floated upward from the silicon substrate 2 insulated by the insulation film 3. A central portion of the RF signal line 5 is associated with the variable capacitor 13, and air layers 12 are provided at both sides of the variable capacitor 13 on the RF signal line 5, by making the RF signal line 5 air-bridged. That is, the RF signal line 5 is air-bridged at locations outside the variable capacitor 13.

Given a control voltage turned on, the lower electrode 7 causes the beam 8 to come downward, till it contacts the dielectric film 9, increasing the capacitance. With the lower electrode 7 given a control voltage turned off, the beam 8 goes upward, so it is spaced off from the dielectric film 9. Like this, there occurs a contacting approach or a spacing between the beam 8 as an associated portion of the ground line 4 and a corresponding portion of the RF signal line 5 provided with the dielectric film 9, whereby the variable capacitor 13 between RF signal line 5 and ground line 4 has a varied capacitance. In other words, the variable capacitor 13 has a varied capacitance, as a contact or dynamic non-contact sate develops between the dielectric film 9 and either or both of the RF signal line 5 and (the beam 8 of upper electrode 6 of) the ground line 4. As illustrated in FIG. 1B, the provision of air layers 12 defined by two rectangular convex portions 10 of the RF signal line 5 implements a series connection of a pair of low capacitances C1, allowing for a reduced stray capacitance.

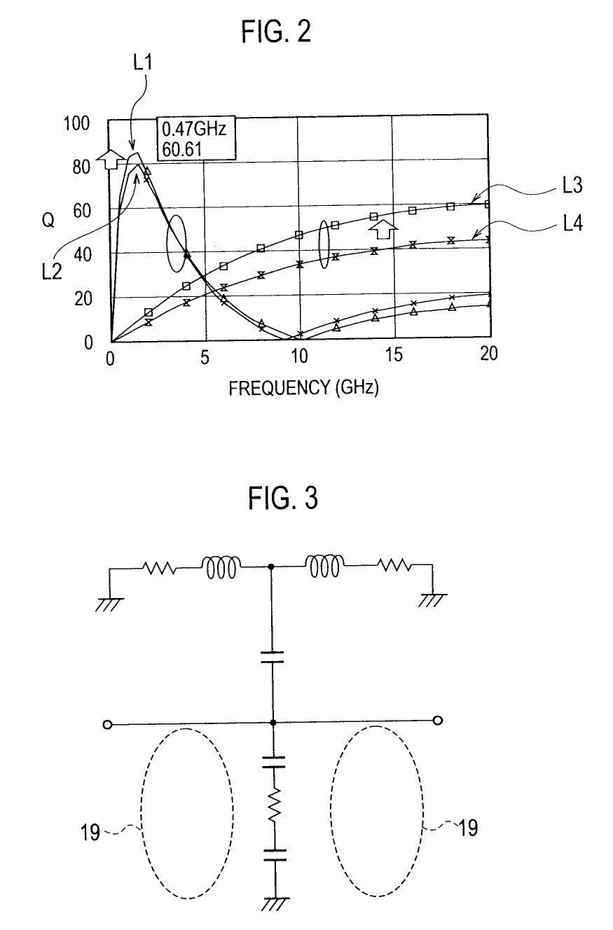

FIG. 2 shows, in a graph, improvements of Q values as results of simulations made of an example of high frequency MEMS 1 illustrated as a high frequency electrical element in FIGS. 1Aa to 1C.

In the graph of FIG. 2, the axis of ordinate represents Q values, and the axis of abscissas represents a frequency, to show variations of the Q values to the frequency. FIG. 2 involves curves L1 and L3 showing variations of Q values in MEMS 1 as the example of the first embodiment illustrated in FIGS. 1A to 1C, and curves L2 and L4 showing Q values in a high frequency MEMS as a comparative example configured without air layers (without being air-bridged). Among them, curves L1 and L2 each show values for a corresponding beam in motion toward a dielectric film with a prescribed control voltage applied to a lower electrode, and curves L3 and L4 each show values for the corresponding beam in motion away from the dielectric film with no control voltage applied to the lower electrode.

As will be seen from comparison of curve L1 with curve L2 in FIG. 2, the high frequency MEMS 1 as an example of the first embodiment has improved Q values in motion of beam toward dielectric film, relative to the high frequency MEMS as a comparative example configured without air layers.

As will be seen from comparison of curve L3 with curve L4, the high frequency MEMS 1 as an example of the first embodiment has improved Q values in motion of beam away from dielectric film, as well, relative to the high frequency MEMS as a comparative example configured without air layers.

It can thus be caught that the high frequency MEMS 1 as an example of the first embodiment has improved Q values relative to the high frequency MEMS as a comparative example configured without air layers, whether on-voltage or off-voltage is applied as the control voltage between upper electrode and lower electrode. It is thus possible to implement a variable capacitor with high values of Q in the first embodiment illustrated in FIGS. 1A to 1C, in which the RF signal line 5 is air-bridged at both outsides of the variable capacitor 13.

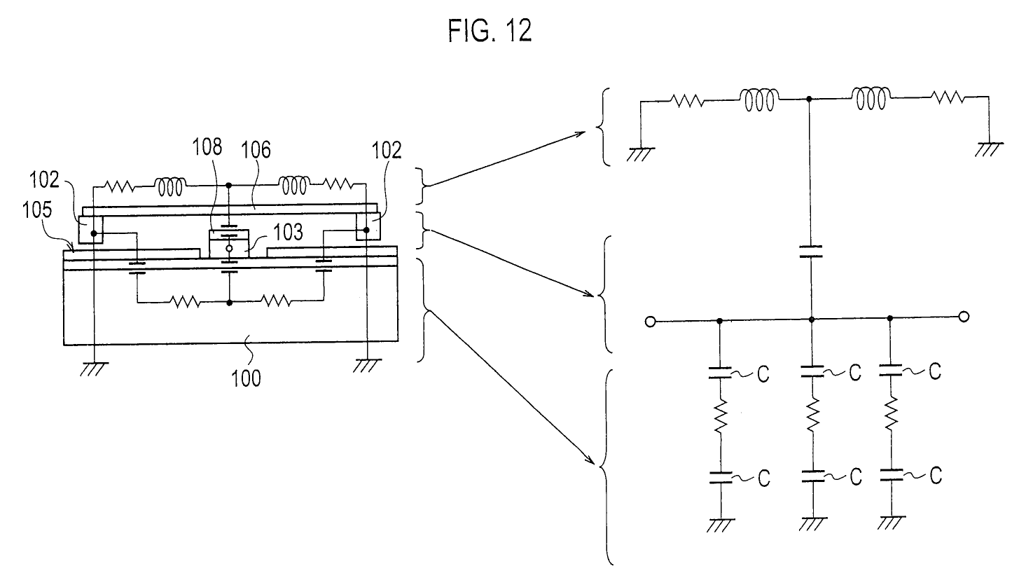

FIG. 3 is an equivalent circuit diagram of the high frequency MEMS 1 as a high frequency electrical element illustrated in FIGS. 1A to 1C. In comparison with the equivalent circuit diagram of general high frequency MEMS illustrated in FIG. 12, stray capacitances are eliminated at areas designated by reference character 19.

### Second Embodiment

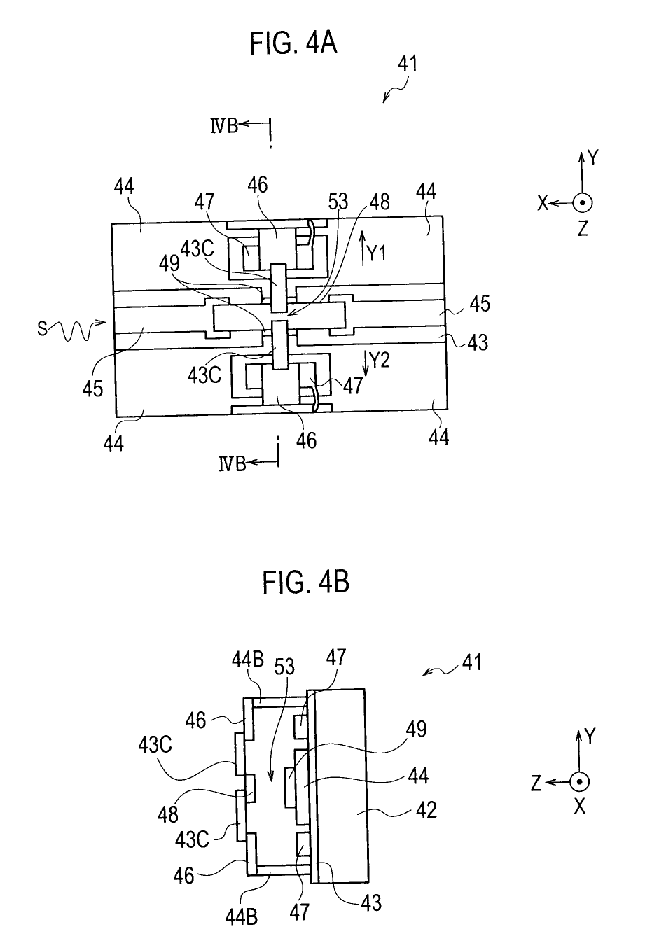

Description is now made of a high frequency electrical element according to a second embodiment of the present invention, with reference to FIGS. 4A and 4B.

FIG. 4A is a plan of a high frequency MEMS 41 as a high frequency electrical element according to the second embodiment, and FIG. 4B, a section along line IVB-IVB of FIG. 4A.

The high frequency MEMS 1 as the first embodiment illustrated in FIGS. 1A to 1C has the RF signal line 5 air-bridged at both outsides of the variable capacitor 13. In the high frequency MEMS 41 as the second embodiment illustrated in FIGS. 4A and 4B, a beam 48 of an RF signal line 45 constituting a variable capacitor 53 is floated from an insulated silicon substrate 42, whereby the RF signal line 45 is air-bridged.

As illustrated in FIGS. 4A and 4B, the high frequency MEMS 41 has the silicon substrate 42 insulated by an insulation film 43. And, on the insulated silicon substrate 42, it has disposed a ground line 44, the RF signal line 45, and a pair of lower electrodes 47.

As illustrated in FIGS. 4A and 4B, the paired lower electrodes 47 are arranged in vertical opposition to a pair of upper electrodes 46, and they are configured as electrodes for producing electrostatic forces to actuate the beam 48 in a Z-axis direction. Respective pairs of vertically opposing upper and electrodes 46 and 47 are disposed at both lateral sides of the RF signal line 45, avoiding extending there below. The beam 48 is widthwise centered to the RF signal line 45, and is linked with and held by the upper electrodes 46 through a pair of linking insulation films 43C at both lateral sides thereof.

As illustrated in FIG. 4B, below the beam 48, there is a dielectric film 49 formed as insulation film on an associated ground portion of the ground line 44. The ground line 44 has a pair of ground portions 44B rising in the X-axis direction on the insulated silicon substrate 42 at both lateral sides of the above-noted associated ground portion, to support the paired upper electrodes 46.

As illustrated in FIG. 4A, the RF signal line 45 is formed in an X-axis direction as a coplanar line to the silicon substrate 42, and receives an RF signal S from an external high frequency electric circuit.

As illustrated in FIG. 4B, the beam 48 as a portion of the RF signal line 45 has an X-directional centerline thereof crossing at right angles in a top view with a Y-directional center-connecting line of the linking insulation films 43C and the upper electrodes 46 as parts of the ground line 44, in a local region above the insulated silicon substrate 42.

Between the beam 48 as a portion of the RF signal line 45 and the associated ground portion, there is a variable capacitor 53 made up by the dielectric film 49 and surrounding air. The variable capacitor 53 has the beam 48 as a portion working as an electrode thereof and air-bridged to define an air layer associated therewith.

Depending on a control voltage applied to the lower electrode 47 being turned on or off, the beam 48 of the RF signal line 45 goes up and down in the Z-axis direction, making a contacting approach or spacing relative to the dielectric film 49, whereby the variable capacitor 53 between RF signal line 45 and ground line 44 has a varied capacitance. In other words, the variable capacitor 53 has a varied capacitance, as a contact or dynamic non-contact sate develops between the dielectric film 49 and either or both of beam 48 as a portion of the RF signal line 45 and an associated ground portion of the ground line 44.

In the second embodiment illustrated in FIGS. 4A and 4B, electrostatic upper electrodes 46 and lower electrodes 47 are disposed in positions at laterally outer sides of the RF signal line 45, i.e., offset in opposite Y1 and Y2 directions from the RF signal line 45 at a center in FIG. 4A. Therefore, the lower electrodes 47 are not disposed anywhere under the beam 48 of the RF signal line 45, allowing for an improved high frequency characteristic. That is, the lower electrodes 47 are not disposed anywhere under any high frequency signal line, but spaced there from, thus constituting no noise source to the high frequency signal line, allowing for an enhanced high frequency characteristic.

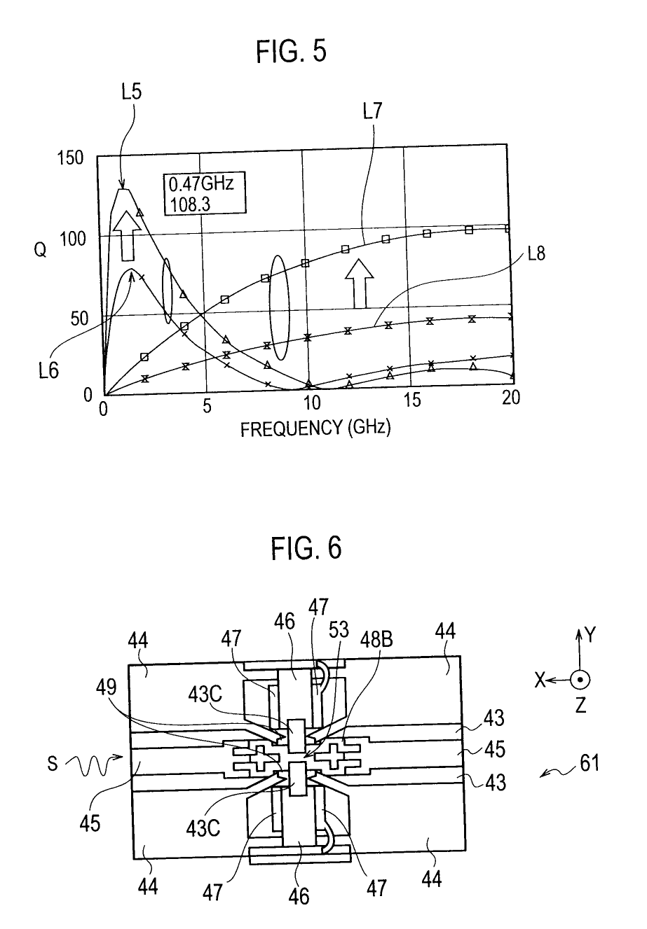

FIG. 5 shows, in a graph, improvements of Q values as results of simulations made of an example of high frequency MEMS 41 illustrated as a high frequency electrical element in FIGS. 4A and 4B.

In the graph of FIG. 5, the axis of ordinate represents Q values, and the axis of abscissas represents a frequency, to show variations of the Q values to the frequency. FIG. 5 involves curves L5 and L7 showing variations of Q values in MEMS 41 as the example of the second embodiment illustrated in FIGS. 4A and 4B, and curves L6 and L8 showing Q values in a high frequency MEMS as a comparative example configured without air layers (without being air-bridged). Among them, curves L5 and L6 each show values for a corresponding beam in motion toward a dielectric film with a prescribed control voltage applied to lower electrodes, and curves L7 and L8 each show values for the corresponding beam in motion away from the dielectric film with no control voltage applied to the lower electrodes.

As will be seen from comparison of curve L5 with curve L6 in FIG. 5, the high frequency MEMS 41 as an example of the second embodiment has improved Q values in motion of beam toward dielectric film, relative to the high frequency MEMS as a comparative example configured without air layers. As will be seen from comparison of curve L7 with curve L8, the high frequency MEMS 1 as an example of the second embodiment has improved Q values in motion of beam away from dielectric film, as well, relative to the high frequency MEMS as a comparative example configured without air layers. It can thus be caught that the high frequency MEMS 41 as an example of the second embodiment has improved Q values relative to the high frequency MEMS as a comparative example configured without air layers, whether on-voltage or off-voltage is applied as the control voltage between upper electrodes and lower electrodes. It is thus possible to implement a variable capacitor with high values of Q in the second embodiment, in which part of the RF signal line 45 constituting an electrode of the variable capacitor is air-bridged.

### Third Embodiment

Description is now made of a high frequency electrical element according to a third embodiment of the present invention, with reference to FIG. 6.

FIG. 6 is a plan of a high frequency MEMS 61 as a high frequency electrical element according to the third embodiment.

The high frequency MEMS 61 as the third embodiment illustrated in FIG. 6 is substantially identical to the high frequency MEMS 41 illustrated in FIGS. 4A and 4B, except for a beam 48B of a spring structure.

The beam 48B is configured with a spring structure for facilitated movements of the upper electrodes 46 in a Z-axis direction. More specifically, the beam 48B is configured with a rectangular electrode plate portion linked at both lateral sides thereof by linking insulation films 43 with upper electrodes 46, and front and rear arm portions interconnecting front and rear sides of the rectangular electrode plate portion and corresponding portions of an RF signal line 45 extending on a silicon substrate insulated by an insulation film 43, each arm portion being divided into two branches and bent to cooperatively define a cross-shaped central void, to thereby provide the spring structure with an increased flexibility. An increased pressing force the beam 48 has against a dielectric film 49 permits lower electrodes 47 for electrostatic actuation to be formed with an increased area, and disposed nearer to the RF signal line 45. With a control voltage applied between upper electrodes 46 and lower electrodes 47, the beam 48 of the spring structure is forced to contact the dielectric film 49. With the voltage to the lower electrodes 47 turned off, the beam 48B is allowed to disengage from the dielectric film 49 by spring forces.

In the third embodiment illustrated in FIG. 6, the lower electrodes 47 for electrostatic actuation can be disposed laterally outside of the RF signal line 45, allowing for an enhanced high frequency characteristic. The electrodes 47 for electrostatic actuation can be offset off, not just under, the high frequency signal line 45, thus constituting no noise source to the high frequency signal line 45, allowing for the more enhanced high frequency characteristic. The spring structure of RF signal line 45 may be combined with a modified layout pattern of lower electrodes 47, as well as of a ground line 44, for still enhanced vertical movements of the beam 48 at a variable capacitor 53.

### Fourth Embodiment

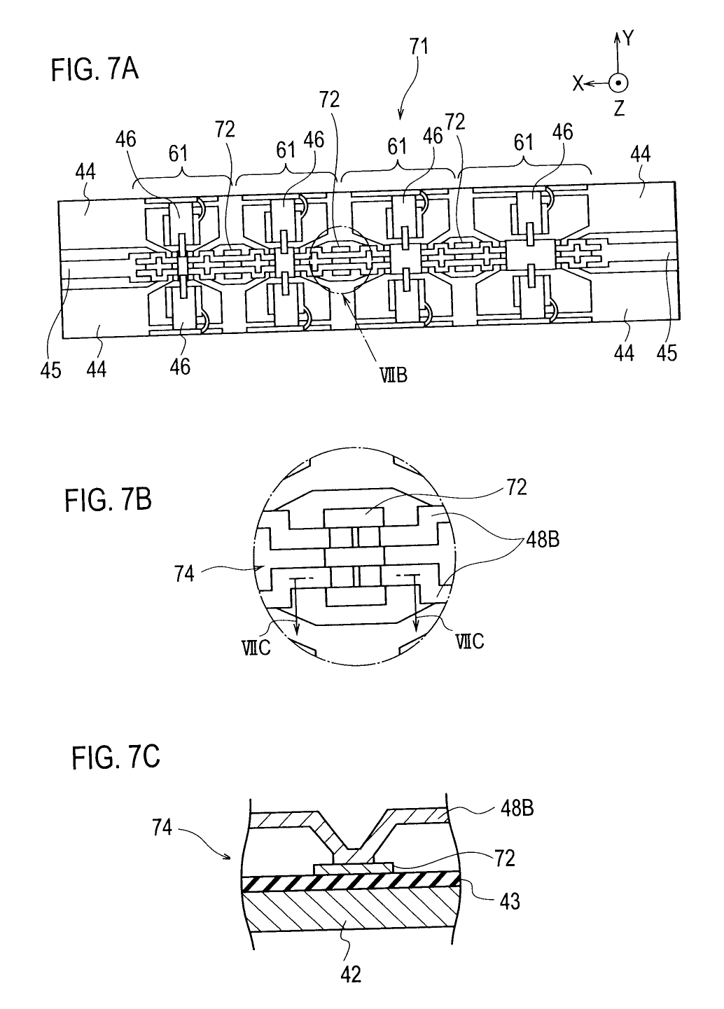

FIG. 7A is a plan of a high frequency MEMS 71 as a high frequency electrical element according to a fourth embodiment of the present invention, FIG. 7B, a detail of part VIIB of FIG. 7A, and FIG. 7C, a section along line VIIC-VIIC of FIG. 7B.

The high frequency MEMS 71 as the fourth embodiment illustrated in FIG. 7A is provided with a capacitor bank composed of a plurality of series-connected unit capacitors each respectively configured as a high frequency MEMS 61 according to the third embodiment illustrated in FIG. 6. In the high frequency MEMS 71 illustrated in FIG. 7A, the capacitor bank is composed of four high frequency MEMS 61, for instance. Those high frequency MEMS 61 have areas of their rectangular electrode plate portions changed in proportion to associated capacitances, in an binary order being 1:2:4:8 for instance, thereby permitting 2⁴=16 combinations of capacitances.

FIG. 7B illustrates an interconnection structure 74 between signal lines as branches of neighboring beams 48B between unit variable capacitors constituting the capacitor bank of the high frequency MEMS 71 illustrated in FIG. 7A. Neighboring beams 48B as air-bridged signal line portions are interconnected by an anchoring structure composed of a metal electrode 72 formed on an insulated silicon substrate 42. Respective sets of signal lines of neighboring beams 48B between unit variable capacitors are connected by anchoring the beams 48B on the metal electrode 72.

### Fifth Embodiment

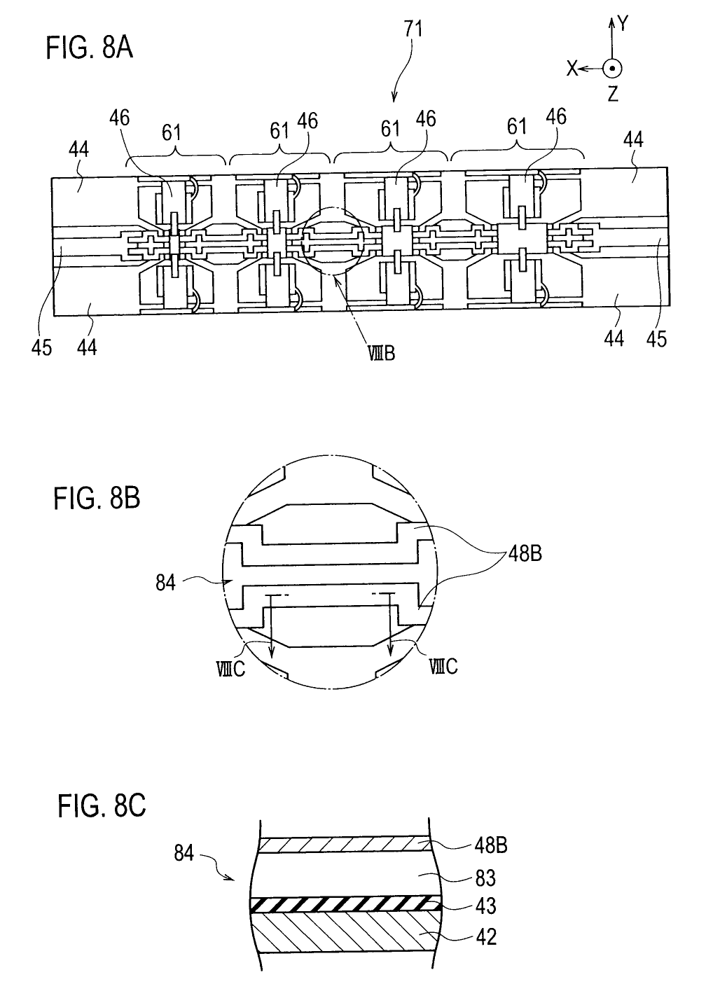

FIG. 8A is a plan of a high frequency MEMS 71 as a high frequency electrical element according to a fifth embodiment of the present invention, FIG. 8B, a detail of part VIIIB of FIG. 8A, and FIG. 8C, a section along line VIIIC-VIIIC of FIG. 8B.

The high frequency MEMS 81 as the fifth embodiment illustrated in FIG. 8A is different from the high frequency MEMS 71 as the fourth embodiment illustrated in FIG. 7A, in that the former has no anchoring structure for interconnection between unit variable capacitors. FIG. 8B illustrates an interconnection structure 84 between signal lines between unit variable capacitors. As illustrated in FIG. 8B, the interconnection structure 84 between signal lines between unit variable capacitors is implemented by a direct connection between signal lines, so lengths of associated beams 48B are air-bridged, cooperating with a silicon substrate 42 insulated by an insulation film 43 to define a connected spatial region 83 therebetween, whereby respective unit variable capacitors are connected to constitute a capacitor bank. Accordingly, the high frequency MEMS 81 can be free of influences of substrate losses at anchor portions, allowing for the more enhanced Q value.

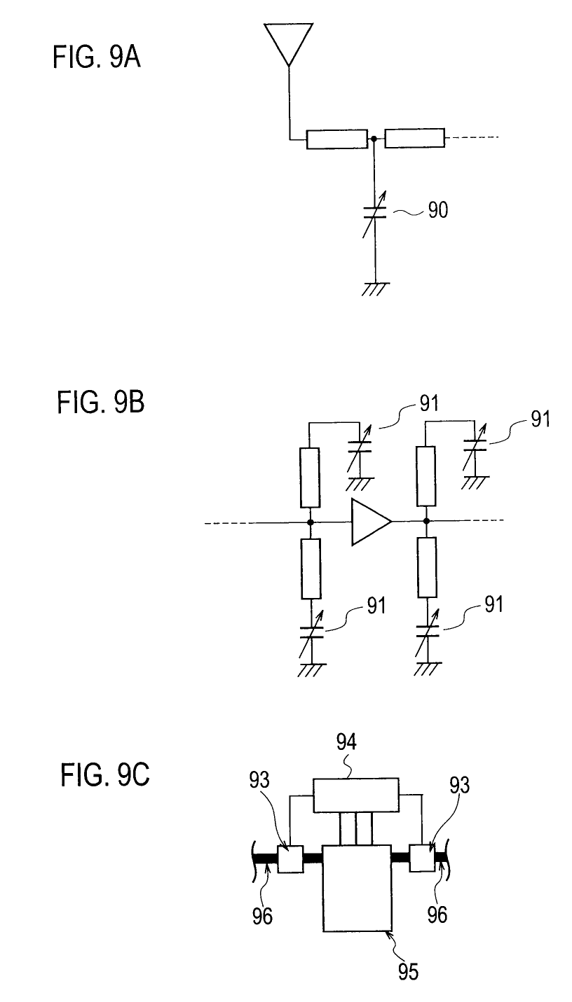

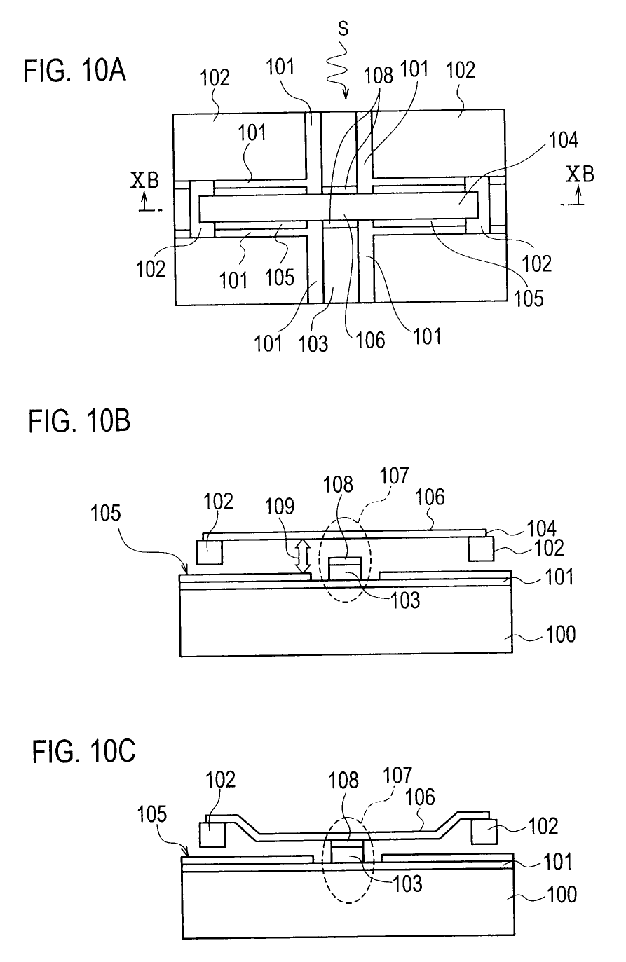

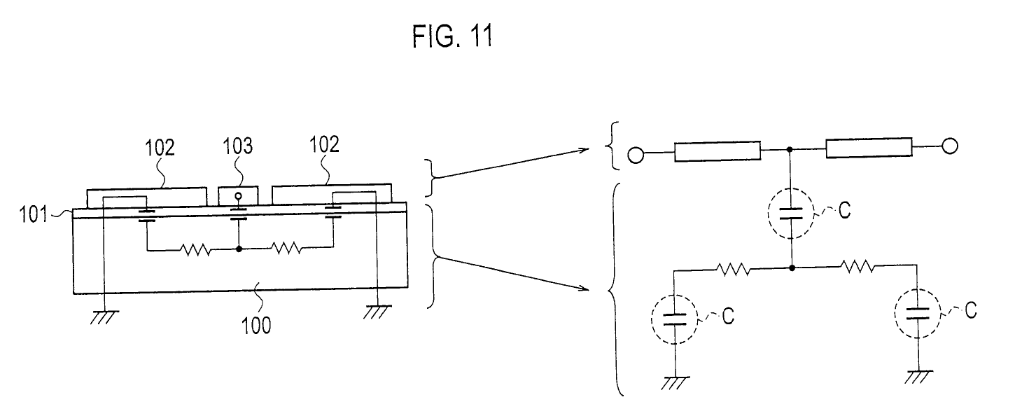

FIGS. 9A to 9C each illustrate an example of circuit diagram including a high frequency MEMS as a high frequency electrical element according to an embodiment of the present invention. In the example of FIG. 9A, a high frequency MEMS 90 is implemented to a tunable antenna, allowing for a miniaturized antenna configuration for a wide-band terrestrial digital broadcasting. In the example of FIG. 9B, high frequency MEMS 91 are implemented as matching circuits of an amplifier, allowing for a reduced number of amplifier types. In the example of FIG. 9C, high frequency MEMS 93 are implemented to a power supply 94 on a silicon substrate using RF connection lines 96 for connection to an amplifier 95.

According to an embodiment of the present invention, a high frequency electrical element comprises a silicon substrate wholly formed with an insulation film, a first signal line provided on the silicon substrate, a second signal line provided on the silicon substrate, the second signal line crossing the first signal line within a first region above the silicon substrate, and a dielectric film interposed between the first signal line and the second signal line, and provided on one of the first signal line and the second signal line, within the first region, the first signal line and the second signal line being relatively movable in directions for a contacting approach and a mutual spacing in between. Permitting a variable capacitor to be implemented with a high Q value, allowing for a reduced circuit loss.

The second signal line comprises a first portion as part of the first region, a second portion extending in a second region different from the first region, the second portion being connected to the first portion, and spaced from the silicon substrate more than the first portion, and a third portion connected to the second portion and a coplanar line formed to the silicon substrate for external connection.

An electrode for electrostatic force for the second signal line to be movable above the silicon substrate is disposed at a lateral side of the second signal line, and the electrode for electrostatic force and the second signal line are linked to each other by a linking insulator, so that the electrode for electrostatic force can be set off, not just under, the second signal line, thus constituting no noise source to the second signal line, allowing for an enhanced high frequency characteristic.

The high frequency electrical element comprises a capacitor bank composed of a plurality of series-connected unit structures each respectively comprising an electrode for electrostatic force disposed at a lateral side of the second signal line, the electrode for electrostatic force being linked to the second signal line by a linking insulator, and the second signal line being connected to a metal electrode on the silicon substrate, and the second signal line at the unit structure is connected to the metal electrode on the silicon substrate, whereas other portions are floated, allowing for an enhanced Q value.

The high frequency electrical element comprises a capacitor bank composed of a plurality of series-connected unit structures each respectively comprising an electrode for electrostatic force disposed at a lateral side of the second signal line, the electrode for electrostatic force being linked to the second signal line by a linking insulator, and the second signal line floating relative to the silicon substrate, and the second signal line at the unit structure is not connected any metal electrode on the silicon substrate, permitting losses at the silicon substrate to be reduced, allowing for an enhanced Q value.

According to an embodiment of the present invention, a second signal line outside a variable capacitor is air-bridged, or a second signal line inside a variable capacitor is air-bridged, permitting a variable capacitor to be implemented with a high Q value, allowing for a reduced circuit loss.

It is noted that according to the present invention, the foregoing embodiments are not restricted as they are, but may be implemented by modifying their components without departing from the spirit.

Components of the foregoing embodiments may be combined in an adequate manner to provide a variety of inventions. For instance, out of whole components of the embodiments, some components may be eliminated. Further, components of different embodiments may be adequately combined.

While preferred embodiments of the present invention have been described using specific terms, such description is for illustrative purposes, and it is to be understood that changes and variations may be made without departing from the scope of the following claims.

What is claimed is:

1. A high frequency electrical element, comprising:
a silicon substrate wholly formed with an insulation film;
a first signal line provided on the silicon substrate;
a second signal line provided on the silicon substrate, the second signal line crossing the first signal line within a first region above the silicon substrate; and
a dielectric film interposed between the first signal line and the second signal line, and provided on one of the first signal line and the second signal line, within the first region,
the first signal line and the second signal line being relatively movable in directions for a contacting approach and a mutual spacing in between.

2. The high frequency electrical element according to claim 1, wherein the second signal line comprises:
a first portion as part of the first region;
a second portion extending in a second region different from the first region, the second portion being connected to the first portion, and spaced from the silicon substrate more than the first portion; and
a third portion connected to the second portion and a coplanar line formed to the silicon substrate for external connection.

3. The high frequency electrical element according to claim 1, wherein an electrode for electrostatic force for the second signal line to be movable above the silicon substrate is disposed at a lateral side of the second signal line, and the electrode for electrostatic force and the second signal line are linked to each other by a linking insulator.

4. The high frequency electrical element according to claim 3, comprising a capacitor bank composed of a plurality of series-connected unit structures each respectively comprising an electrode for electrostatic force disposed at a lateral side of the second signal line, the electrode for electrostatic force being linked to the second signal line by a linking insulator, and the second signal line being connected to a metal electrode on the silicon substrate.

5. The high frequency electrical element according to claim 3, comprising a capacitor bank composed of a plurality of series-connected unit structures each respectively comprising an electrode for electrostatic force disposed at a lateral side of the second signal line, the electrode for electrostatic force being linked to the second signal line by a linking insulator, and the second signal line floating relative to the silicon substrate.
